(19) United States
(12) Patent Application Publication
(10) Pub. No.: US 2022/0085825 A1
(43) Pub. Date: Mar. 17, 2022

(54) POWER SUPPLY DRIVE CIRCUIT

(71) Applicant: DENSO CORPORATION, Kariya-city (JP)

(72) Inventor: Masatarou IWAMOTO, Kariya-city (JP)

(21) Appl. No.: 17/534,544

(22) Filed: Nov. 24, 2021

Related U.S. Application Data
(63) Continuation of application No. PCT/JP2020/020560, filed on May 25, 2020.

(30) Foreign Application Priority Data
Jun. 10, 2019 (JP) 2019-107901

(51) Int. Cl. H03M 1/66; H03K 3/01

(52) U.S. Cl. CPC H03M 1/66; H03K 3/01

(57) ABSTRACT

A power supply drive circuit includes a primary-side power supply drive circuit and a secondary-side power supply circuit. The primary-side power supply drive circuit has a digital-to-analog converter for executing soft-start control of a primary-side power supply circuit with a predetermined step amount. The primary-side power supply circuit generates a predetermined primary-side voltage from a power supply voltage. The secondary-side power supply drive circuit drives a secondary-side power supply circuit that lowers the predetermined primary-side voltage to generate a predetermined secondary-side voltage. The digital-to-analog converter further sets a step amount for an output of the digital-to-analog converter to be smaller than the predetermined step amount based on a condition that the output is in a vicinity of the predetermined secondary side voltage.

### CROSS REFERENCE TO RELATED APPLICATIONS

The present application is a continuation application of International Patent Application No. PCT/JP2020/020560 filed on May 25, 2020, which designated the U.S. and claims the benefit of priority from Japanese Patent Application No. 2019-107901 filed on Jun. 10, 2019. The entire disclosures of all of the above applications are incorporated herein by reference.

### TECHNICAL FIELD

The present disclosure relates to a power supply drive circuit.

### BACKGROUND

A power supply circuit may include a primary-side power supply circuit and a secondary-side power supply circuit. The primary-side power supply circuit lowers a power supply voltage, and the secondary-side power supply circuit further lowers the output of the primary-side power supply circuit. In the power supply circuit, soft-start may be executed for the primary-side power supply circuit to suppress the generation of overshoot at the time of starting.

### SUMMARY

The present disclosure describes a power supply drive circuit including a primary-side power supply drive circuit and a secondary-side power supply drive circuit.

### BRIEF DESCRIPTION OF DRAWINGS

Objects, features and advantages of the present disclosure will become more apparent from the following detailed description made with reference to the accompanying drawings. In the drawings:

FIG. 1 illustrates an electric configuration according to a first embodiment;

FIG. 2 illustrates an electrical configuration diagram of a digital-to-analog converter (DAC);

FIG. 3 is a waveform diagram of a voltage Vdac of the DAC;

FIG. 4 illustrates an electric configuration of a DAC according to a second embodiment;

FIG. 5 is a waveform diagram of a voltage Vdac of the DAC;

FIG. 6 illustrates an electric configuration of a DAC according to a third embodiment; and

FIG. 7 is a waveform diagram of a voltage Vdac of the DAC.

### DETAILED DESCRIPTION

A digital-to-analog converter (DAC) may be adopted for executing soft-start control of a primary-side power supply circuit included in a power supply circuit. In this configuration, when a power supply voltage is lowered at the time of starting, the output voltage with a voltage increased with a predetermined step width is provided to the primary-side power supply circuit from the DAC, and the overshoot may be suppressed.

Even though such soft-start control is executed, when a secondary-side power supply included in the power supply circuit is generated from the primary-side power supply, the overshoot exceeding the predetermined secondary voltage may be generated in the vicinity of the secondary-side voltage caused by a potential difference in the step width of the DAC under the soft-start control. The above situation may be caused by the control delay of an operational amplifier. Therefore, the overshoot in the secondary-side power supply circuit may be generated along with a variation in the output of the DAC.

Such an overshoot may be significantly improved as compared with a case without the soft-start control. However, the secondary-side power supply circuit may be adversely affected, in a case where the power is supplied to a circuit where the tolerance range of the output of the secondary-side voltage is narrower.

It may be considered to shorten the step amount for the output of the DAC. However, to increase a voltage until reaching the final voltage with a smaller step amount, it may be required to have the DAC with higher resolution as a whole. Therefore, it may lead to an increase in the cost.

According to an aspect of the present disclosure, a power supply drive circuit includes a primary-side power supply drive circuit and a secondary-side power supply circuit. The primary-side power supply drive circuit has a digital-to-analog converter for executing soft-start control of a primary-side power supply circuit with a predetermined step amount. The primary-side power supply circuit generates a predetermined primary-side voltage from a power supply voltage. The secondary-side power supply drive circuit drives a secondary-side power supply circuit that lowers the predetermined primary-side voltage to generate a predetermined secondary-side voltage. The digital-to-analog converter further sets a step amount for an output of the digital-to-analog converter to be smaller than the predetermined step amount based on a condition that the output is in a vicinity of the predetermined secondary-side voltage.

By adopting the above configuration, when the primary-side power supply drive circuit adopts the output voltage of the digital-to-analog converter to execute the soft-start control of the primary-side power supply circuit, the step width in the vicinity of the secondary-side voltage is set to be a smaller step amount than the predetermined step amount. Therefore, it is possible to further suppress the overshoot in the vicinity of the secondary-side voltage. Therefore, in a case where the secondary-side power supply drive circuit lowers the primary-side voltage, it is possible to output the secondary-side power supply with better precision by further suppressing the overshoot in the vicinity of the secondary-side voltage.

In the circuit that utilizes the secondary-side voltage, the overshoot exceeding the secondary-side voltage is suppressed. Therefore, it is possible to utilize the circuit with a narrower allowable voltage step without having an adverse effect or damage.

### First Embodiment

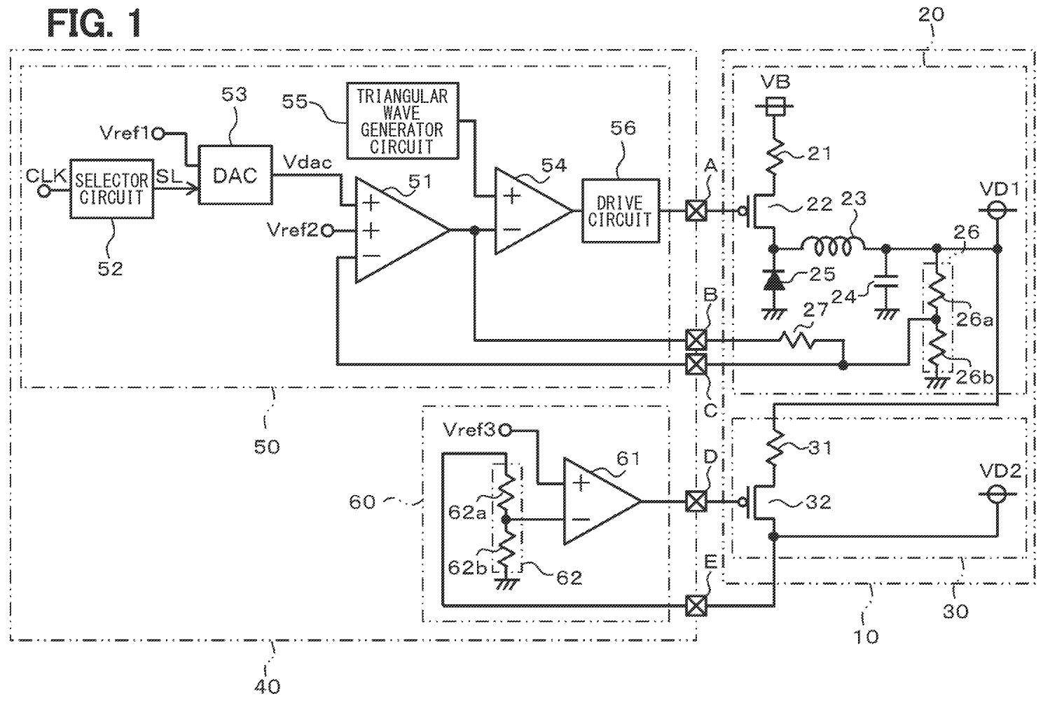

A first embodiment will be described with reference to FIGS. 1 to 3.

FIG. 1 illustrates an entire circuitry configuration. A power supply circuit 10 includes a primary-side power supply circuit 20 and a secondary-side power circuit 30. The control of the power supply circuit 10 is driven by a power supply drive circuit 40. The power supply drive circuit 40 includes a semiconductor integrated circuit such as an ASIC. The power supply drive circuit 40 includes terminals A to E. The power supply drive circuit 40 includes a primary-side power supply drive circuit 50 and a secondary-side power supply drive circuit 60.

The primary-side power supply circuit 20 generates a predetermined primary-side voltage VD1 by a direct current (DC) power supply VB such as a battery through step-down control. A series circuit including a resistor 21, a P-channel MOSFET 22, a coil 23 and a capacitor 24 is connected between the DC power supply VB and ground. The common connection node between the MOSFET 22 and the coil 23 is connected to the ground through a diode 25 in a reversed direction. The gate of the MOSFET 22 is connected to the terminal A of the power supply drive circuit 40.

The common connection node between the coil 23 and the capacitor 24 is connected to the output terminal of the primary-side voltage VD1. A series circuit including a resistor 26a and a resistor 26b in a voltage divider circuit 26 is connected between the output terminal of the primary-side voltage VD1 and the ground. The common connection node between the resistors 26a and 26b is connected to the terminal C of the power supply drive circuit 40, and is connected to the terminal B through a resistor 27.

The secondary-side power supply circuit 30 further lowers the primary-side voltage VD1 to generate a predetermined secondary-side voltage VD2. The output terminal of the primary-side voltage VD1 is connected to the output terminal of the secondary-side voltage VD2 through a series path having a resistor 31 and a P-channel MOSFET 32. The gate of the MOSFET 32 is connected to the terminal D of the power supply drive circuit 40, and the output terminal of the secondary-side voltage VD2 is connected to the terminal E of the power supply drive circuit 40.

In the power supply drive circuit 40, the primary-side power supply drive circuit 50 drives the primary-side power supply circuit 20, and generates the primary-side voltage VD1 through soft-start control as a countermeasure against overshoot. The primary-side power supply drive circuit 50 includes an error amplifier 51, a selector circuit 52, a digital-to-analog converter (DAC) 53, a comparator 54, a triangular wave generator circuit 55 and a drive circuit 56. The error amplifier 51 includes an inverting input terminal and two non-inverting input terminals.

One of the non-inverting input terminals of the error amplifier 51 receives the voltage Vdac provided from the output terminal of the DAC 53. The DAC 53 outputs the voltage Vdac and changes the voltage Vdac stepwise for soft-start control. The DAC 53 receives a reference voltage Vref, and receives a selection signal SL from the selector circuit 52. The selector circuit 52 receives a clock signal CLK, and outputs the selection signal SL that sequentially switches the output of the DAC 53 with reference to the timing of the clock signal CLK. In the present disclosure, the selector circuit may also be referred to as a selection circuit.

The other one of the non-inverting input terminals of the error amplifier 51 receives a reference voltage Vref2. A divided voltage of the primary-side voltage VD1 acquired from the divider circuit having the resistors 26 and 27 is provided to the inverting input terminal of the error amplifier 51 through the terminal C. The reference voltage Vref2 is set as a voltage for outputting the primary-side voltage VD1, and the reference voltage Vref1 may be a voltage larger than or equal to the reference voltage Vref2. The error amplifier 51 computes the difference between the smallest voltage of the voltages respectively provided to two non-inverting input terminals of the error amplifier 51 and the divided voltage of the primary-side voltage VD1 provided to the inverting input terminal of the error amplifier 51.

The comparator 54 has an inverting input terminal connected to the output terminal of the error amplifier 51 and the terminal B, and has a non-inverting input terminal connected to receive a triangular wave signal from the triangular wave generator circuit 55. The output terminal of the comparator 54 is connected to the terminal A through the driver circuit 56. The driver circuit 56 applies a gate voltage to the MOSFET 22 of the primary-side power supply circuit 20 to control the drive.

The secondary-side power supply drive circuit 60 controls the drive of the secondary-side power supply circuit 30, and includes an error amplifier 61 and a voltage divider circuit 62. The voltage divider circuit 62 is a series circuit having resistors 62a and 62b, and is connected between the terminal E and the ground. The non-inverting input terminal of the error amplifier 61 receives a reference voltage Vref3. The reference voltage Vref3 is a voltage for outputting the secondary-side voltage VD2 of the secondary-side power supply circuit 30. The inverting input terminal of the error amplifier 61 is connected to the common connection node between the resistors 62a and 62b of the voltage divider circuit 62. The error amplifier 61 applies a gate voltage from the output terminal of the error amplifier 61 to the MOSFET 32 of the secondary-side power supply circuit 30 through the terminal D for the control of drive.

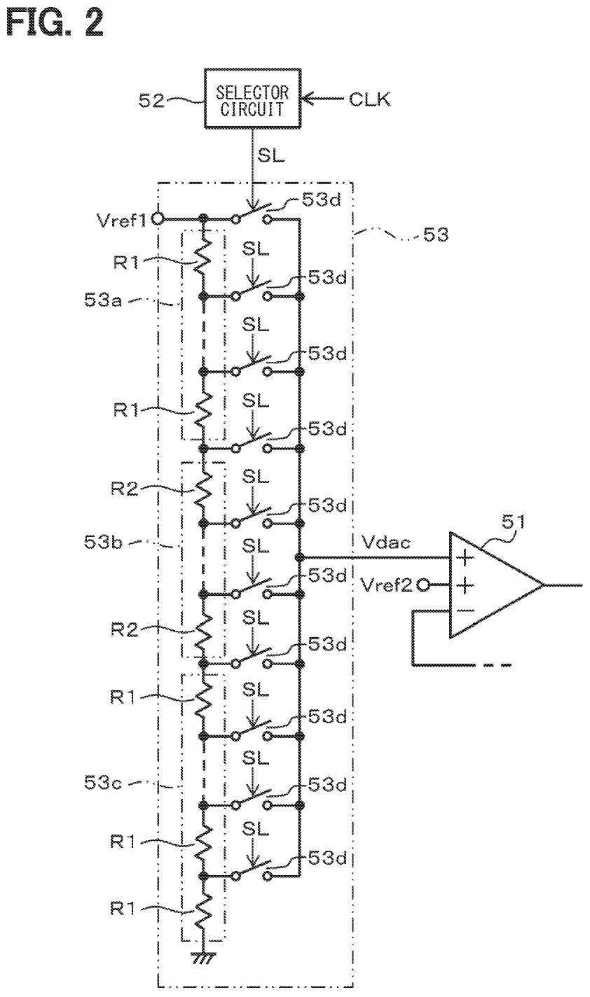

The following describes the electrical configuration of the DAC 53 with reference to FIG. 2. The DAC 53 has an essential configuration having resistive strings 53a, 53b, 53c connected between the input terminal of the reference voltage Vref1 and the ground. The resistive strings 53a, 53b, 53c are respectively series circuits. Each of the series circuits has multiple resistors. The resistive strings 53a and 53c are series circuits with multiple resistors R1, and the resistive string 53b is a series circuit with multiple resistors R2. The resistor R1 had a resistance value R, and the resistor R2 has a resistance value R/2.

Each of the connection nodes respectively between the resistors R1 and between the resistors R2 included in the resistive strings 53a, 53b, 53c is connected to the output terminal through a switch 53d, and the voltage at the connection node of the switch 53d which is switched on is output as the voltage Vdac. The output terminal of the DAC 53 is connected to one of the non-inverting input terminals of the error amplifier 51.

Multiple switches 53d in the DAC 53 are configured to be turned on sequentially from the lowermost switch 53d to the upper side of the switches 53d through the selection signal SL provided from the selector circuit 52. The DAC 53 outputs the voltage Vdac that sequentially increases with a predetermined step width from time t0, t1 to tn (n is a natural number) with a time interval T. In the present disclosure, the step width may also be referred to as a voltage step and a step amount.

The portion where the resistance value of the resistor R2 in the resistive string 53b is set to a half of the resistance value of the resistor R1 in the DAC 53 is set such that the level of the output voltage Vdac is in a range of the predetermined voltages covering the secondary-side voltage VD2. As a result, in a case where the soft-start control of the primary-side power supply circuit 20 is executed, the control for further shortening the step width of the voltage is executed in a range of the predetermined voltages covering the secondary-side voltage VD2.

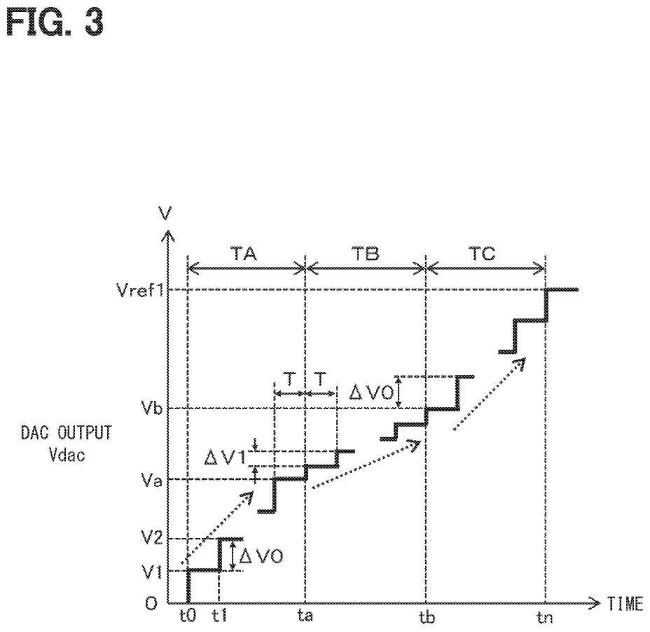

Next, an operation of the above-mentioned configuration will be described with reference to FIG. 3. The following describes the operation of the power supply drive circuit 40 for the primary-side power supply circuit 20 and the secondary-side power supply circuit 30, and further describes the soft-start control.

The primary-side power supply drive circuit 50 starts a control operation, and then computes the difference voltage between the voltage received form the terminal C and the voltage Vdac received from the DAC 53 at the error amplifier 51 and then outputs the difference voltage. In the error amplifier 51, the reference voltage Vref2 as one of the voltages respectively provided to two non-inverting input terminals is set to a level for setting the predetermined primary-side voltage VD1. Since the voltage Vdac received from the DAC 53 is smaller, the difference voltage with respect to the Vdac is computed as the operation.

At this time, the voltage Vdac from the DAC 53 is stepped up with the step width ΔV0 from a zero level by the selection signal SL provided from the selector circuit 52 in a period T of the clock signal CLK. Therefore, in the error amplifier 51, in a state where the primary-side voltage VD1 has not been generated, since a feedback voltage provided to the inverting input terminal is in the vicinity of 0V, the difference voltage is calculated as a small level and is output to the comparator 54. The period T of the clock signal CLK may also be referred to as a cycle of the clock signal CLK.

The comparator 54 compares a triangular wave signal provided from the triangular wave generator circuit 55 with the signal of the difference voltage from the error amplifier 51 to generate a pulse-width-modulation (PWM) signal, and then output the PWM signal to the driver circuit 56. The driver circuit 56 turns on and off the MOSFET 22 of the primary-side power supply circuit 20 according to the PWM signal.

As a result, the DC voltage VB is conducted from the coil 23 to the capacitor 24 through the MOSFET 22, and is output towards the capacitor 24 as a gradually rising voltage, and then the operation is executed by soft-start control. Since the MOSFET 22 is driven on and off for a short time, a surge current does not flow in and the overshoot having a smaller amount occurs every time the voltage Vdac of the DAC 53 rises in a stepwise manner, however, the voltage Vdac gradually rises in a state where the overshoot is reduced until reaching the predetermined primary-side voltage VD1.

The secondary-side power supply drive circuit 60 controls the drive of the MOSFET 32 of the secondary-side power supply circuit 30 to execute the step-down operation such that the secondary-side voltage VD2 reaches a predetermined level. In this case, since the primary-side voltage VD1 is small and does not reach the setting voltage of the secondary-side voltage VD2 immediately after starting, the primary-side voltage VD1 is output.

When the primary-side voltage VD1 approaches the setting voltage of the secondary-side voltage VD2, the error amplifier 61 detects the level of the secondary-side voltage VD2 provided from the terminal E through a voltage divided by the voltage divider circuit 62, and drives the MOSFET 32 until reaching the reference voltage Vref3.

When the above operation is executed, in the secondary-side power supply drive circuit 60, when the secondary-side voltage VD2 is generated, the secondary-side voltage VD2 rises in a state following the variation in the primary-side voltage VD1. Therefore, in a state where the soft-start control is executed at the time of starting, the overshoot having a smaller amount occurs every time the voltage Vdac of the DAC 53 increases in a stepwise manner due to the circuitry delay.

In this embodiment, the DAC 53 operates such that the overshoot is further suppressed in a case where the small overshoot in the soft-start control of the primary-side power supply circuit 20 is severe in the generation of the secondary-side voltage VD2 in the secondary-side power supply circuit 30. The DAC 53 is set such that the step width of the voltage Vdac decreases in a predetermined range covering the vicinity of the secondary-side voltage VD2, in other words, the predetermined range covering the secondary-side voltage VD2, by setting the resistance value of each of the resistors R2 in the resistive string 53b to a value of R/2.

FIG. 3 illustrates a time transition of the voltage Vdac of the DAC 53 which is switched and output by the selector signal SL that sequentially changes at the predetermined time interval T. The reference voltage Vref1 is divided at a connection node between the resistors R1 and at a connection node between the resistors R2.

As the switch 53d connected to the resistive string 53c is selectively turned on by the selector signal SL, in the period TA from the time t0 to time ta, the voltage Vdac becomes voltages V1, V2 . . . Va, which are obtained by sequentially adding the voltage ΔV0 divided at the resistor R1. The voltage ΔV0 is regarded as a step width.

Subsequently, as the switch 53d connected to the resistive string 53b is selectively turned on by the selector signal SL, in the period TB from the time t0 to time tb, the voltage Vdac becomes voltages Va, . . . Vb which are obtained by sequentially adding the voltage ΔV1 divided at the resistor R2. The voltage ΔV1 is also regarded as a step width.

The voltage ΔV1 is a half the voltage of the voltage ΔV0. The voltage Vdac having the voltage ΔV1 as a step width is set in a range between the voltage Va to the voltage Vb, in other words, a range from a lower predetermined voltage to a upper predetermined voltage covering the secondary-side voltage VD2, as a range of the predetermined voltages in the vicinity of the secondary-side voltage VD2. As a result, the overshoot is further reduced when the secondary-side voltage VD2 is generated by the secondary-side power supply circuit 30.

Subsequently, as the switch 53a connected to the resistive string 53d is selectively turned on by the selector signal SL, in the period TC from the time tb to time tn, the voltage Vdac becomes voltages Vb . . . Vref which are obtained by sequentially adding the voltage ΔV0 divided at the resistor R1. The voltage ΔV0 is also regarded as a step width. The primary-side voltage VD1 is generated in the primary-side power supply circuit 20. In the period TC, the error amplifier 61 is controlled such that the secondary-side voltage VD2 is within a predetermined level range.

In the first embodiment, in the primary-side power supply drive circuit 50, the voltage Vdac output by the DAC 53 is added by the predetermined step width ΔV0, and then the step width is set to ΔV1 as a half of the step width ΔV0 in a range from the voltage Va to the voltage Vb as the predetermined voltages in the vicinity of the secondary-side voltage VD2, in other words, in a range from the lower predetermined voltage to the upper predetermined voltage covering the secondary-side voltage VD2. Therefore, the reduction in the overshoot of the soft-start control can be further reduced in the vicinity of the secondary-side voltage VD2.

In the first embodiment, in the DAC 53, the resistance value of the resistor R2 of the resistive string 53b is set to a half of the resistance value R1 of the resistors in the resistive strings 53a, 53c to decrease the step width partially.

As a result, according to the above embodiment, since the DAC 53 partially reduces the step width without setting the DAC 53 at a higher resolution, it is possible to suppress the cost without a large modification of the circuitry configuration.

In a case where there is a margin in the setting width of the voltage Vdac as the configuration of the DAC 53, it is possible to set the voltage Vdac with a smaller step width until reaching the primary-side voltage VD1, as the resistive string 53a adopts the resistor R2 identical to the one in the resistive string 53b.

### Second Embodiment

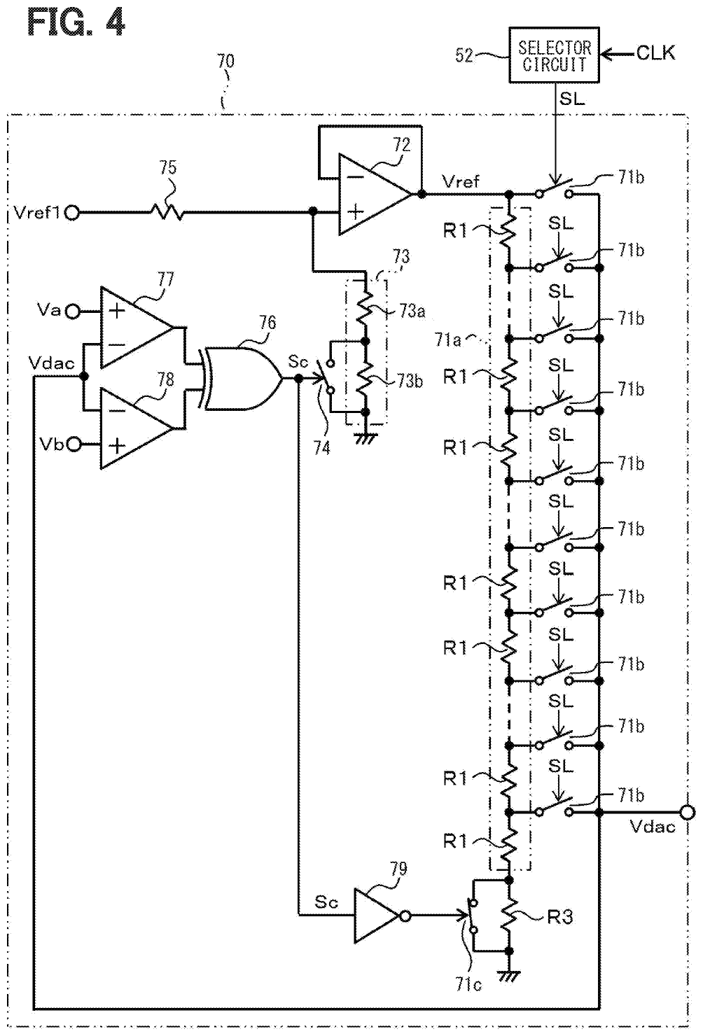

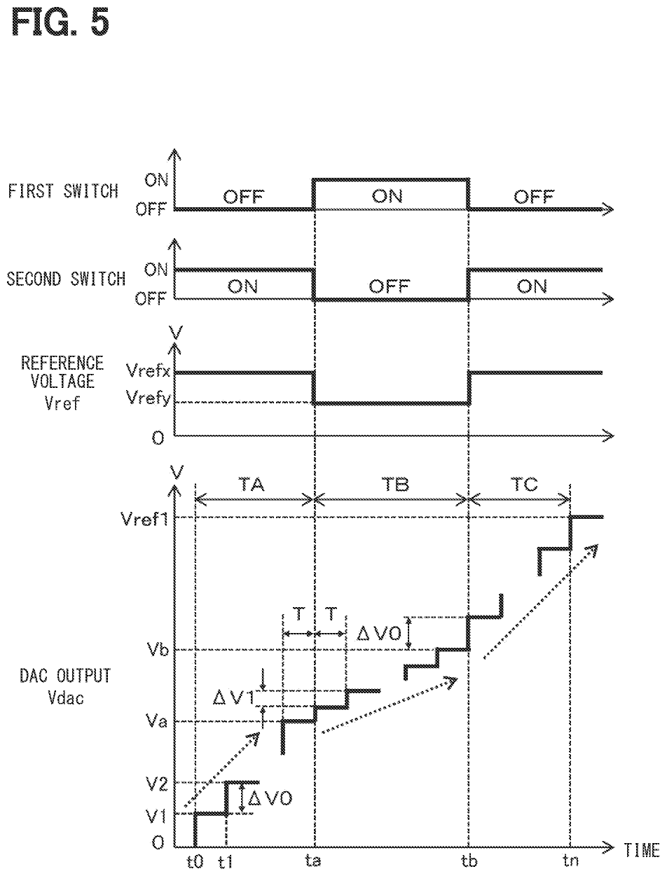

The following describes a second embodiment with reference to FIGS. 4, 5, and describes the parts different from the first embodiment. This embodiment provides a DAC 70 as a digital-to-analog converter in replacement of the DAC 53 in the primary-side power supply driver circuit 50.

FIG. 4 illustrates the configuration of the DAC 70. A resistive string 71a is a series circuit having multiple resistors R1, and the resistor R3 is connected to the resistive string in series at the ground side. Each connection node in each of the resistors R1 in the resistive string 71a is commonly connected to the output terminal through each corresponding one of the switches 71b. The switch 71b is sequentially and selectively turned on from the lower side by the selection signal SL output from the selector circuit 52.

A switch 71c is connected to the resistor R3 in parallel, and is in a short-circuit state by turning on the switch 71c. The upper end of the resistive string 71a is connected to the output terminal of an operational amplifier 72 for a buffer, and receives the reference voltage Vref. In the operational amplifier 72, the inverting input terminal and the output terminal are commonly connected, and the non-inverting input terminal is connected to the ground through a divider circuit 73.

The divider circuit 73 includes a series circuit having resistors 73a and 73b. A switch 74 is connected to the resistor 73b in parallel, and is in the short-circuit state by turning on the switch 74. The non-inverting input terminal of the operational amplifier 72 receives the reference voltage Vref through a resistor 75.

The switch 74 is controlled to be turned on and off through an output signal Sc of a logic circuit 76. The logic circuit 75 executes an exclusive OR operation, and the respective output terminals of the comparators 77, 78 are connected to two input terminals of the logic circuit 76. The comparator 77 receives a voltage Va at the non-inverting input terminal, and the inverting input terminal of the comparator 77 is connected to the output terminal of the DAC 70, and receives the voltage Vdac. The comparator 78 receives a voltage Vb at the non-inverting input terminal, and the inverting input terminal of the comparator 78 is connected to the output terminal of the DAC 70, and receives the voltage Vdac.

The voltage Va is preliminarily set as a voltage immediately before the voltage Vdac of the output terminal of the DAC 70 increases from 0V at a step width of ΔV0 and is switched to the step width ΔV1. The voltage Vb is preliminarily set as a voltage immediately before the voltage Vdac of the output terminal of the DAC 70 increases from the voltage Va at a step width of ΔV1 and is switched to the step width ΔV0. The range from the voltage Va to Vb, in other words, the range from the lower voltage to the upper voltage covering the secondary-side voltage VD2 is set. The voltages Va and Vb are the predetermined voltages in the vicinity of the secondary-side voltage VD2.

The switch 71c connected to the resistor R3 of the resistive string 71a in parallel receives the output signal Sc of the logic circuit 76 through an inverter 79. When the output signal Sc of the logic circuit 76 is at the low level, the switch 74 is at the off-state, and the switch 71c is at the on-state. When the output signal Sc of the logic circuit 76 is at the high level, the switch 74 is at the on-state, and the switch 71c is at the off-state.

When the voltage Vdac of the output terminal of the DAC 70 is smaller than the voltage Va, each of the comparators 77 and 78 outputs the high-level signal. Therefore, the logic circuit 76 outputs the low-level signal Sc. When the voltage Vdac of the output terminal of the DAC 70 is larger than the voltage Vb, each of the comparators 77 and 78 outputs the low-level signal. Therefore, the signal Sc of the logic circuit 76 is at the low level.

When the voltage Vdac of the output terminal of the DAC 70 is larger than or equal to the voltage Va and is lower than or equal to the voltage Vb, the comparator 77 outputs the low-level signal and the comparator 78 outputs the high-level signal. Therefore, the signal Sc of the logic circuit 76 is at the high level.

When the voltage Vdac of the output terminal of the DAC 70 is smaller than the voltage Va or is larger than the voltage Vb, the switch 74 is maintained at the off-state by the low-level signal Sc, and the resistor 73b is at the effective state, the switch 71c is at the on-state, and the resistor R3 is at the short-circuit state.

When the voltage Vdac of the output terminal of the DAC 70 is larger than or equal to the voltage Va and is smaller than or equal to the voltage Vb, the switch 74 is operated at the on-state by the high-level signal Sc, the resistor 73b is switched to the short-circuit state, the switch 71c is switched to the off-state, and the resistor R3 is at the effective state.

Next, the action of the above configuration will be described with reference to FIG. 5.

In this embodiment, the DAC 70 is different from the first embodiment, and the resistance value of each of the resistors R1 in the resistive string 71a is set to the identical resistance value R. However, by switching the reference voltage Vref, the step width of the voltage Vdac is set to be smaller in the vicinity of the secondary-side voltage VD2.

FIG. 5 illustrates a time transition of the voltage Vdac of the DAC 70 which is switched and output by the selector signal SL that sequentially changes at the predetermined time interval T. In the initial state, since the voltage Vdac is zero, each of the comparators 77 and 78 outputs high-level signals, and the logic circuit 76 outputs the low-signal signal Sc. Therefore, the switch 71c is held in the on-state and the switch 74 is held in the off-state.

As a result, in the initial state, as illustrated in FIG. 5, the reference voltage Vref1 is provided as a reference voltage Vrefx through the operational amplifier 72 to the resistive string 71a, in a state where the reference voltage Vref1 is divided at the resistors 75, 73a, 73b. The resistor R3 is in the short-circuit state. The resistive string 71a divides the reference voltage Vrefx with the resistance value R at the connection node between the resistors R1.

As the switch 71d connected to the resistive string 71a is selectively turned on by the selector signal SL of the selector circuit 52, in the period TA from the time t0 to time ta, the voltage Vdac becomes voltages V1, V2 . . . Va, which are obtained by sequentially adding the voltage ΔV0 divided at the resistor R1. The voltage ΔV0 is regarded as a step width.

When the voltage Vdac reaches Va, the output of the comparator 77 is inverted to the low level. Therefore, the logic circuit 76 outputs the high-level signal Sc. As a result, the switch 71c is switched to the off-state, and the switch 74 is switched to the on-state.

The resistor R3 is switched from the short-circuit state to a state where the resistor R3 is connected to the resistive string 71a in series, and the resistor 73b is in the short-circuit state. In this state, as illustrated in FIG. 5, the reference voltage Vref1 is provided as a reference voltage Vrefy through the operational amplifier 72 to the resistive string 71a, in a state where the reference voltage Vref1 is divided at the resistors 75, 73a. The resistor R3 is in the effective state.

As a result, in the present setting state of the switch 71b, the voltage Vdac holds the state of the voltage Va. When the switch 71b is switched according to the subsequent selection signal SL, for the voltage Vdac during the period TB from the time ta to time tb, the voltage shared by the resistor R1 becomes the voltage Va . . . Vb added sequentially with the voltage ΔV1, but not the voltage ΔV0, as the step width.

The voltage ΔV1 is a half the voltage of the voltage ΔV0. The output Vdac having the voltage ΔV1 as a step width is set in a range between the voltage Va to the voltage Vb, in other words, a range from a lower predetermined voltage to a upper predetermined voltage including the secondary-side voltage VD2, as a range of the predetermined voltages in the vicinity of the secondary-side voltage VD2. As a result, the overshoot is further reduced when the secondary-side voltage VD2 is generated by the secondary-side power supply circuit 30.

Subsequently, when the switch 71b connected to the resistive string 71a is driven on by the selection signal SL and the voltage Vdac reaches the voltage Vb, the output of the comparator 78 is inverted to the low level. Therefore, the logic circuit 76 outputs the low-level signal Sc. As a result, the switch 71c is switched to the on-state, and the switch 74 is switched to the off-state.

Then, the resistor R3 is again in the short-circuit state, the terminal of the resistive string 71a at the ground side is at the ground level. The short-circuit state of the resistor 73b is lifted and is in the effective state, as illustrated in FIG. 5, the reference voltage Vref1 is provided as a reference voltage Vrefx through the operational amplifier 72 to the resistive string 71a, in a state where the reference voltage Vref1 is divided at the resistors 75, 73a, 73b.

As a result, in the present setting state of the switch 71b, the voltage Vdac holds the state of the voltage Vb. When the switch 71b is switched according to the subsequent selection signal SL, for the voltage Vdac during the period TC from the time tb to time tn, the voltage shared by the resistor R1 becomes the voltage Vb . . . Vref1 added sequentially with the voltage the voltage ΔV0 as the step width. The primary-side voltage VD1 is generated in the primary-side power supply circuit 20.

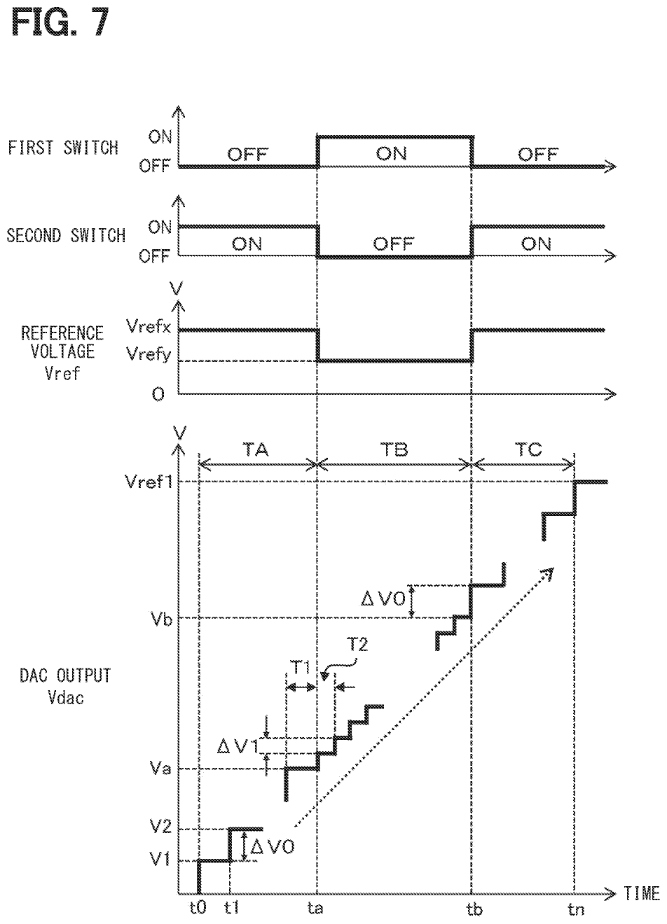

In the present disclosure, the switch 74 may be also referred to as a first switch as illustrated in FIGS. 5 and 7, and the switch 71b may also be referred to as a second switch as illustrated in FIGS. 5 and 7.

Therefore, the same operation and effects as those of the first embodiment can be obtained by the second embodiment.

In the second embodiment, it is possible to generate the similar advantageous effect with the configuration of having the resistive string 71a with a series circuit of the resistors R1 and additional circuits such as logic circuits 76, the comparators 77, 78.

The configuration with the additional circuits for switching the reference voltage is not only limited to the one illustrated in the above embodiments, it is also possible to adopt another circuitry configuration that exhibits the identical advantageous effect.

### Third Embodiment

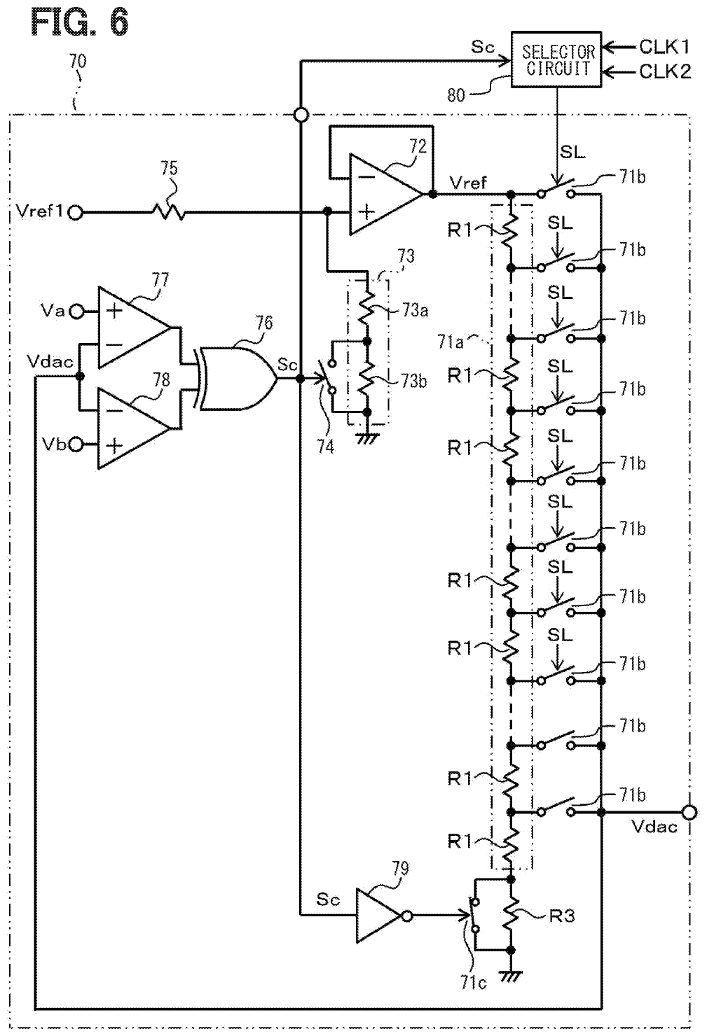

The following describes a third embodiment with reference to FIGS. 6, 7, and describes the parts different from the second embodiment. In this embodiment, the switching period of the switch 71b during the period TB described in the second embodiment can be modified.

In the first and second embodiments, in the period TB, the voltage Vdac output from the DAC 53 or the DAC 70 becomes the voltage ΔV1 as a half of the voltage ΔV0. As a result, voltage rise per time unit is also halved. In this embodiment, the clock signal CLK is also set to have a half period so that the voltage rise per time unit becomes constant as a whole.

In this embodiment, a selector circuit 80 is provided in replacement of the selector circuit 52 as shown in FIG. 6. The selector circuit 80 receives a clock signal CLK2 with a half of the period T2 in addition to the clock signal CLK1 of the period T1 identical to the second embodiment. The selector circuit 80 receives the output signal Sc of the logic circuit 76.

When the selector circuit 80 receives the low-level signal Sc from the logic circuit 76, the selector circuit 80 sequentially outputs the selection signal SL in the period T1 of the clock signal CLK1. When the selector circuit 80 receives the high-level signal Sc from the logic circuit 76, the selector circuit 80 sequentially outputs the selection signal SL in the period T2 of the clock signal CLK2.

As illustrated in FIG. 7, the DAC 70 during the periods TA and TC changes such that the voltage Vdac is stepped up with the step width ΔV0 through the selection signal SL provided from the selection signal 80 with the period T1. The DAC 70 during the period TB changes such that the voltage Vdac is stepped up with the step width ΔV1 through the selection signal SL provided from the selector circuit 80 with the period T2.

As a result, a voltage change rate dV(1)/dt can be expressed in the following mathematical formula (1) in the periods TA, TC. As a result, a voltage change rate dV(2)/dt can be expressed in the following mathematical formula (2) in the period T. Since the step width ΔV1 is a half of the step width ΔV0 and the period T2 is a half of the period T1, the mathematical formula (2) then becomes a mathematical formula (3), which is identical to the mathematical formula (1).

$$\begin{matrix}dV ( 1 ) / d t = Δ V 0 / T 1 & ( 1 ) \\ dV ( 2 ) / d t = Δ V 1 / T 2 \\ dV ( 2 ) / d t = ( Δ V 0 / 2 ) / ( T 1 / 2 ) = Δ V 0 / T 1 = dV ( 1 ) / dt & ( 2 )\end{matrix}$$

In the third embodiment, in the primary-side power supply drive circuit 50, the voltage Vdac output by the DAC 70 is added by the step width ΔV0 in each period T1 during the periods TA and TC and output, and the voltage Vdac is added by the step width ΔV1 in each period T2, in a range from the voltage Va to the voltage Vb, in other words, in the range of the predetermined voltages including the secondary-side voltage VD2. The voltages Va and Vb are predetermined voltages in the vicinity of the secondary-side voltage VD2. Therefore, it is possible to control with the identical average voltage rising rate dV/dt in all of the periods from the period TA to the period TC, and it is possible to further reduce the voltage rising rate in the vicinity of the secondary-side voltage VD2.

In the above embodiment, the selector circuit 80 adopts the clock signals CLK1, CLK2 for switching. However, it is possible to adopt a clock circuit with a clock signal having a shorter period or cycle to switch to multiple time period or cycle by dividing the clock signal inside the selector circuit 80.

In addition, although the above embodiment has been described as being applied to the third embodiment, the above embodiment can also be applied to the configuration of the first embodiment.

The period T1 may also be referred to as a cycle T1, and the period T2 may also be referred to as a cycle T2 in the present disclosure.

### Other Embodiments

The present disclosure should not be limited to the embodiments described above. Various embodiments may further be implemented without departing from the scope of the present disclosure, and may be modified or expanded as described below.

Each of the above embodiments describes a voltage range from the voltage Va to Vb, in other words, a range from a lower voltage to an upper voltage covering the secondary-side voltage VD2. However, the voltages Va, Vb may be set with an equal voltage width such that the width between the upper voltage and the second-side voltage VD2 and the width between the lower voltage and the second-side voltage VD2 are equal. Additionally, the voltages Va, Vb may be set with a different voltage width.

The present disclosure has been described based on examples, but it is understood that the present disclosure is not limited to the examples or structures. The present disclosure encompasses various modifications and variations within the scope of equivalents. In addition, various combinations and configurations, as well as other combinations and configurations that include only one element, more, or less, fall within the scope and spirit of the present disclosure.

What is claimed is:

1. A power supply drive circuit comprising:
a primary-side power supply drive circuit having a digital-to-analog converter configured to execute soft-start control of a primary-side power supply circuit with a predetermined step amount, the primary-side power supply circuit generating a predetermined primary-side voltage from a power supply voltage; and
a secondary-side power supply drive circuit configured to drive a secondary-side power supply circuit that lowers the predetermined primary-side voltage to generate a predetermined secondary-side voltage,
wherein the digital-to-analog converter of the primary-side power supply drive circuit is further configured to set a step amount for an output of the digital-to-analog converter to be smaller than the predetermined step amount, based on a condition that the output is in a vicinity of the predetermined secondary-side voltage.

2. The power supply drive circuit according to claim 1,
wherein the digital-to-analog converter includes a series circuit having a plurality of resistors connected in series, and the series circuit has a predetermined resistance value provided by a group of the resistors,
wherein the series circuit is configured to output a divided voltage acquired by dividing a reference voltage through at least one of the resistors, and
wherein the digital-to-analog converter is further configured to set a resistance value provided by another group of the resistors in the series circuit to be smaller than the predetermined resistance value, in order to set the step amount for the output of the digital-to-analog converter to be smaller than the predetermined step amount based on the condition that the output is in the vicinity of the predetermined secondary-side voltage.

3. The power supply drive circuit according to claim 1,
wherein the digital-to-analog converter includes a structure having a resistor providing a predetermined resistance value, and the digital-to-analog converter is configured to output a divided voltage acquired by dividing a first reference voltage through the resistor in the structure,
wherein the digital-to-analog converter is further configured to switch the first reference voltage to a second reference voltage in the structure, in order to set the step amount for the output of the digital-to-analog converter to be smaller than the predetermined step amount based on the condition that the output is in the vicinity of the predetermined secondary-side voltage, and
wherein the second reference voltage is lower than the first reference voltage.

4. The power supply drive circuit according to claim 2, further comprising:
a selector circuit configured to switch a cycle of a selection signal provided to the digital-to-analog converter,
wherein the digital-to-analog converter is further configured to shorten a cycle per voltage step for the output of the digital-to-analog converter through the selector circuit based on the condition that the output is in the vicinity of the predetermined secondary-side voltage, such that an average change in the output of the digital-to-analog circuit over time is identical in a period during which the cycle of the selection signal is shortened by the selector circuit and in a period during which the digital-to-analog converter does not set the step amount to be smaller than the predetermined step amount.

5. The power supply drive circuit according to claim 1,
wherein the digital-to-analog converter of the primary-side power supply drive circuit sets the step amount for the output of the digital-to-analog converter to be smaller than the predetermined step amount, based on the condition that the output is in a voltage range from a lower predetermined voltage to an upper predetermined voltage and covering the predetermined secondary-side voltage.
